(19) United States
(12) Patent Application Publication
(10) Pub. No.: US 2024/0319587 A1
(43) Pub. Date: Sep. 26, 2024

(54) IMPRINT METHOD AND TEMPLATE FOR IMPRINTING

(71) Applicant: Kioxia Corporation, Tokyo (JP)

(72) Inventors: Yukichi KAMITA, Yokkaichi Mie (JP); Daisuke KOMATSU, Yokkaichi Mie (JP); Akihiko ANDO, Yokkaichi Mie (JP)

(73) Assignee: Kioxia Corporation, Tokyo (JP)

(21) Appl. No.: 18/593,159

(22) Filed: Mar. 1, 2024

(30) Foreign Application Priority Data
Mar. 20, 2023 (JP) 2023-043754

(51) Int. Cl. G03F 7/00; G03F 7/20

(52) U.S. Cl. CPC G03F 7/0002; G03F 7/2004

(57) ABSTRACT

An imprint method forms a pattern by pressing a template including a pattern surface having an uneven portion against an imprinting region of a photocurable imprint material provided on a substrate. The imprint method includes preparing a template having an adjacent light transmission restricting film on a pattern surface, preparing the substrate including the imprint material, and pressing the pattern surface against the imprint material and irradiating the imprint material with light. In irradiating the imprint material with light, the imprint material in the imprinting region and the imprint material raised at an end edge of the pattern surface adjacent to the imprinting region are exposed, the imprint material in the imprinting region is cured and the imprint material is cured while maintaining a height and a shape of the imprint material that is raised at the adjacent position.

### CROSS-REFERENCE TO RELATED APPLICATION

This application is based upon and claims the benefit of priority from Japanese Patent Application No. 2023-043754, filed Mar. 20, 2023, the entire contents of which are incorporated herein by reference.

### FIELD

Embodiments described herein relate generally to an imprint method and a template for imprinting.

### BACKGROUND

Imprint lithography for forming an etching mask by pressing a template against a resist layer is known. In imprint lithography, a resist layer may be formed on the entire surface of a film to be etched by a spin coating method.

### DESCRIPTION OF THE DRAWINGS

FIG. 1 is a diagram schematically showing a state in which a resist layer is imprinted using a template according to a first embodiment.

FIG. 2 is a diagram schematically showing a partial cross section of the template.

FIGS. 3A and 3B are plan views showing an example of a region to be imprinted on a resist layer by the template.

FIGS. 4A to 4E are schematic diagrams showing a state in which a resist layer is imprinted using a template according to the first embodiment in stages.

FIGS. 5A to 5D are schematic diagrams showing a state in which a resist layer is imprinted by a template of a comparative example in stages.

FIGS. 6A to 6C are schematic diagrams showing a state in which a resist layer after imprinting by a template in a comparative example in stages.

FIGS. 7A to 7F are schematic diagrams showing a method for manufacturing a template according to a first example in stages.

FIGS. 8A and 8B are schematic diagrams showing a template and an imprinting state of a first modification example used in an imprint method.

FIGS. 9A to 9D are schematic diagrams showing a state in which the imprint method is performed using the template of the first modification example in stages.

FIGS. 10A and 10B are schematic diagrams showing a template and an imprinting state of a second modification example used in an imprint method.

FIGS. 11A and 11B are schematic diagrams showing a template and an imprinting state of a third modification example used in an imprint method.

FIGS. 12A to 12C are schematic diagrams showing a template and an imprinting state of a fourth modification example in stages used in an imprint method.

FIG. 13 is a schematic diagram showing a template and an imprinting state of a fifth modification example used in an imprint method.

FIG. 14 is a plan view showing an example of a region to be imprinted on a resist layer with the template.

FIG. 15 is a schematic diagram showing a template and an imprinting state of a sixth modification example used in an imprint method.

FIGS. 16A to 16C are schematic diagrams showing a template and a stamping state of seventh to ninth modification examples used in an imprint method.

### DETAILED DESCRIPTION

Embodiments provide an imprint method and a template for imprinting that reduce defects such as pattern filling due to a resist layer.

In general, according to one embodiment, there is provided an imprint method for forming a pattern by pressing a light-transmitting template including a pattern surface having an uneven portion against an imprinting region of a photocurable imprint material provided on a substrate. A template including a light transmission restricting film adjacent to the pattern surface is prepared, and the substrate including the imprint material is prepared. The method includes performing imprinting by irradiating the imprint material with light in a state where the pattern surface is pressed against the imprint material. When the imprint material is irradiated with light, the imprint material in the imprinting region and the imprint material raised at an end edge of the pattern surface adjacent to the imprinting region are exposed, and the imprint material in the imprinting region is cured. In addition, a raised portion of the imprint material that is raised on the end edge is cured while maintaining a height and a shape of the raised portion.

Hereinafter, non-limiting embodiments will be described with reference to the accompanying drawings.

In all the drawings attached, the same or corresponding members or components are denoted by the same or corresponding reference numerals, and duplicate description thereof will be omitted. In addition, the drawings are not intended to show the relative thicknesses between members or components or between various layers. Therefore, specific thicknesses and dimensions may be determined by those skilled in the art in view of the following non-limiting embodiments.

### First Embodiment

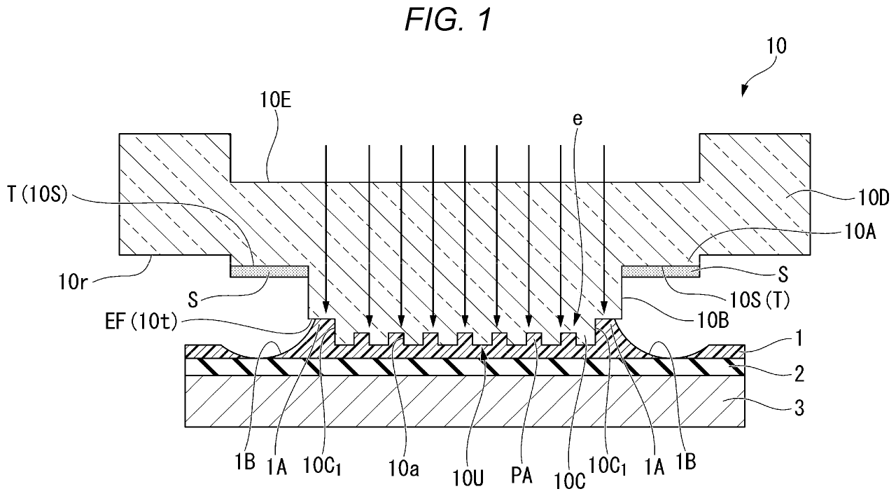

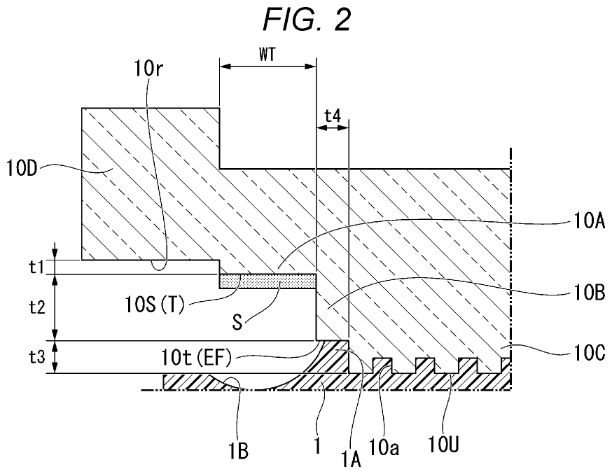

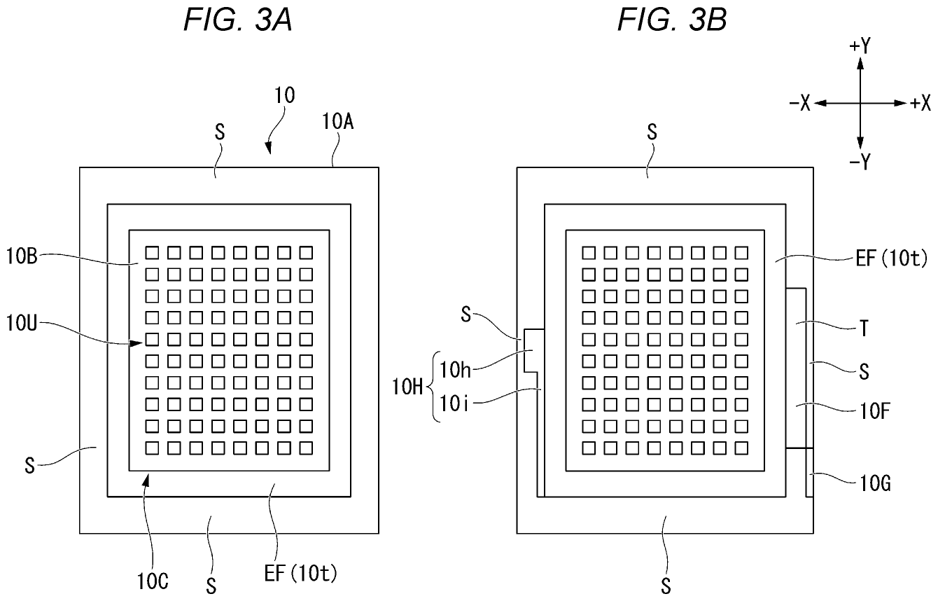

FIG. 1 is a cross-sectional view schematically showing a template 10 according to a first embodiment, a resist layer 1 of an object to be imprinted by the template 10, a target film 2 including the resist layer 1, and a substrate (wafer) 3 including the target film 2. FIG. 2 is a diagram schematically showing a partial cross section of the template 10, and FIG. 3A is a diagram schematically showing a lower surface of the template 10. The substrate includes, for example, a semiconductor substrate such as a silicon wafer.

In the description of the present embodiment, the lower surface refers to a surface of the template 10 on a side facing the resist layer 1 when the template 10 is pressed against the resist layer 1.

The resist layer 1 is a layer of a liquid applied on the target film 2 by an application method such as a spin coating method, and the resist layer 1 corresponds to an example of a layer configured with a resist corresponding to the imprint material.

The template 10 is formed of a material capable of transmitting light (for example, ultraviolet rays), for example, quartz glass or resin, and as shown in the drawings, has a first mesa portion 10A, a second mesa portion 10B, a third mesa portion 10C, and a base material portion 10D. The base material portion 10D has a substantially quadrangular plan view shape. A depressed portion 10E is formed on an upper surface of the base material portion 10D.

The first mesa portion 10A has a substantially quadrangular plan view shape in the present embodiment, and protrudes downward from substantially the center of a lower surface of the base material portion 10D. The second mesa portion 10B has a substantially quadrangular plan view shape in the present embodiment, and protrudes downward from a substantially center of a lower surface of the first mesa portion 10A.

As shown in FIG. 2, a height difference (level difference) t1 between a lower surface 10r of the base material portion 10D and a lower surface 10S of the first mesa portion 10A may be, for example, several tens of μm. The height difference (level difference) t2 between the lower surface 10S of the first mesa portion 10A and the lower surface 10t of the second mesa portion 10B may be, for example, several tens of μm. An example of the shape of the first mesa portion 10A and the second mesa portion 10B in a plan view is shown in FIG. 3A.

The third mesa portion 10C has a substantially quadrangular plan view shape in the present embodiment, and protrudes downward from the lower surface 10t of the second mesa portion 10B. The lower surface 10U of the third mesa portion 10C includes an uneven portion 10a corresponding to the pattern to be formed by a photoresist. The lower surface 10U of the third mesa portion 10C may be referred to as a pattern surface.

The height difference (level difference) t3 (refer to FIG. 2) between the lower surface (pattern surface) 10u of the third mesa portion 10C and the lower surface 10t of the second mesa portion 10B may be, for example, about 200 nm to 500 nm, or about 2 to 5 times a depth of the pattern. The height difference is larger than the height difference of the uneven portion 10a. In addition, each side of the third mesa portion 10C in the plan view can have a length in a range of, for example, several mm to several cm.

In the present specification, when a numerical range is defined by the upper limit and the lower limit using “to”, unless otherwise specified, the numerical range means a range of the lower limit value or more and the upper limit value or less. Therefore, for example, 200 nm to 500 nm means a range of 200 nm or more and 500 nm or less.

As shown in FIG. 1, as described above, in the template 10 according to the present embodiment, the lower surface 10U of the third mesa portion 10C is a pattern surface forming the uneven portion 10a.

The entire lower surface of the third mesa portion 10C (the entire pattern surface) corresponds to the imprinting region e (also referred to as a shot region) in the resist layer 1.

In the present embodiment, the third mesa portion 10C is smaller than the second mesa portion 10B in a plan view, and is concentrically disposed with the second mesa portion 10B as shown in FIG. 3A. That is, in a plan view, the center of the third mesa portion 10C and the center of the second mesa portion 10B may coincide with each other, and each side of the third mesa portion 10C may be parallel to the corresponding side of the second mesa portion 10B. In the periphery of the third mesa portion 10C in the plan view, the lower surface 10t of the second mesa portion 10B may be present as a second median surface EF, and the second median surface EF may have a constant width on each side. Hereinafter, a width t4 (refer to FIG. 2) of the second median surface EF may be several μm, for example, 1 to 2 μm.

In the present embodiment, the second mesa portion 10B is smaller than the first mesa portion 10A in a plan view and is concentrically disposed with the first mesa portion 10A as shown in FIG. 3A. That is, in a plan view, the center of the second mesa portion 10B and the center of the first mesa portion 10A may coincide with each other, and each side of the second mesa portion 10B may be parallel to the corresponding side of the first mesa portion 10A. The lower surface 10S of the first mesa portion 10A may be disposed around the second mesa portion 10B, and the lower surface 10S may have a constant width on each side. A width WT (refer to FIG. 2) of the lower surface 10S having the constant width may be, for example, several μm.

A light-shielding portion S functioning as a light transmission restricting film is formed on the lower surface 10S of the first mesa portion 10A along the four sides of the first mesa portion 10A. The light-shielding portion S, for example, may be formed by coating with a metal or the like. As the material forming the light-shielding portion S, for example, a material including one or more of a metal material, an oxide thereof, a nitride thereof, and an oxynitride thereof may be used. Specific examples of the above-described metal materials include chromium (Cr), molybdenum (Mo), tantalum (Ta), tungsten (W), zirconium (Zr), titanium (Ti), and the like.

By forming the light-shielding portion S from these materials, the light-shielding portion S can block the transmission of light. It is preferable that the light-shielding portion S has a transmittance of 10% or less when irradiated with ultraviolet rays having a wavelength of 365 nm, for example.

In the examples shown in FIGS. 1 and 2, the shape of the light-shielding portion S in the plan view is a quadrangular frame shape that surrounds the periphery of the second median surface EF having a quadrangular frame shape in the plan view with a uniform width, as shown in FIG. 3A. However, the shape of the light-shielding portion S in the plan view is not limited to the shape shown in FIG. 3A.

For example, as shown in FIG. 3B, in the light-shielding portion S having a quadrangular frame shape in a plan view, a first median surface exposure portion 10F in which the light-shielding portion S is not partially provided on a +X direction side from the right side portion and the first median surface T is partially exposed may be provided. In the following description, with respect to the light-shielding portion S having a quadrangular frame shape in the plan view shown in FIG. 3B, a direction in which a short side extends is assumed to be a X direction, and a direction in which a long side extends is assumed to be a Y direction.

The Y direction is a direction that intersects (for example, is orthogonal to) the X direction. The +X direction and the −X direction are directions different from each other by 180°, and the +Y direction and the −Y direction are directions different from each other by 180°.

The first median surface exposure portion 10F has a vertically long rectangular shape extending in the Y direction in a plan view. The Y-direction length of the first median surface exposure portion 10F is, for example, about one-severalth of the Y-direction length of the light-shielding portion S on the right side. The X-direction width of the first median surface exposure portion 10F is, for example, slightly smaller than the X-direction width on the long side of the light-shielding portion S. When viewed in a plan view, the −X direction end of the first median surface exposure portion 10F reaches the X direction end of the second median surface EF. The light-shielding portion S having a small width in the X direction is left as it is on the right side of the first median surface exposure portion 10F in the plan view.

In addition, as shown in FIG. 3B, in the light-shielding portion S in the plan view, a second median surface exposure portion 10G having a vertically long rectangular shape extending in the Y direction may be provided in the vicinity of the first median surface exposure portion 10F. The second median surface exposure portion 10G has a smaller width in the X direction and a shorter length in the Y direction than the first median surface exposure portion 10F in a plan view.

In the example shown in FIG. 3B, the second median surface exposure portion 10G is provided on the +X direction side and the −Y direction side from the first median surface exposure portion 10F in the plan view.

The −X direction end and the +Y direction end of the second median surface exposure portion 10G coincide with the +X direction end and the −Y direction end of the first median surface exposure portion 10F in the plan view. The +X direction end of the second median surface exposure portion 10G reaches the +X direction end on the right side of the light-shielding portion S in the plan view.

In addition, as shown in FIG. 3B, in the light-shielding portion S having a quadrangular frame shape in a plan view, a third median surface exposure portion 10H in which the first median surface T is exposed by not partially providing the light-shielding portion S on the −X direction side from the left portion may be provided.

The third median surface exposure portion 10H may be provided with a wide portion 10h having a vertically long rectangular shape with a slightly larger width in the Y direction in a plan view and a narrow portion 10i having a small width in the X direction and a slender shape in the Y direction. The wide portion 10h is a left side of the light-shielding portion S having a quadrangular frame shape in a plan view, and is formed at a position continuous with a Y-direction central portion on the left side of the light-shielding portion S in the plan view. The X-direction width of the wide portion 10h is slightly larger than half of the X-direction width of the left portion of the light-shielding portion S. Therefore, the light-shielding portion S having a narrow width is left on the −X direction side of the wide portion 10h. The narrow portion 10i extends in the Y direction with a +X direction end edge in a plan view coinciding with a −X direction end position of the left side portion of the second median surface EF. The −Y direction end of the narrow portion 10i is formed up to the position of the −Y direction end of the second median surface EF.

A template having the first to third median surface exposure portions 10F to 10H shown in FIG. 3B may be used.

### Imprint Method

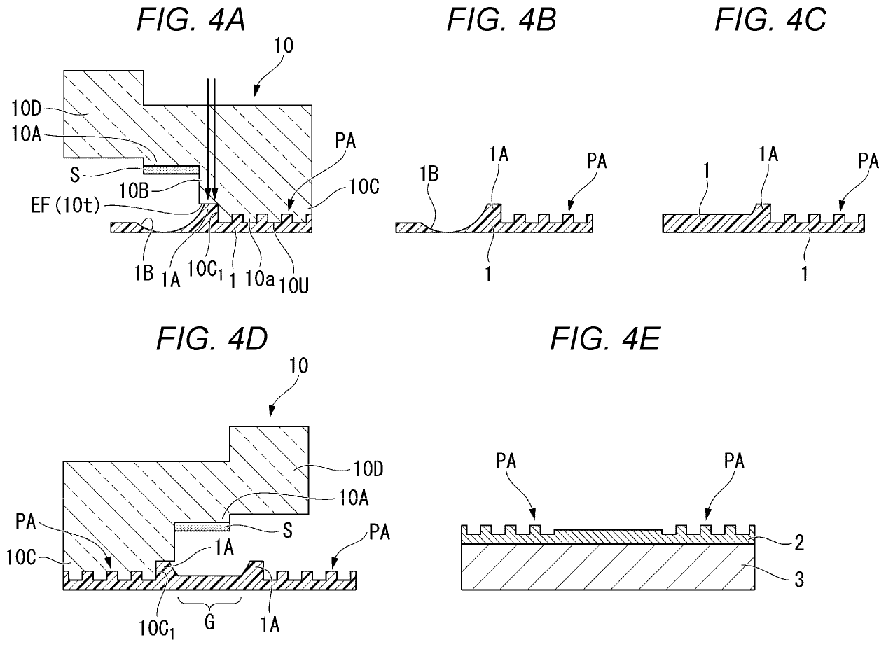

Next, an imprint method using the template 10 according to the first embodiment will be described with reference to FIGS. 1 and 4. The imprint method may be performed, for example, as a part of a method for manufacturing a semiconductor device.

A substrate 3 including the resist layer 1 and the target film 2 described above is prepared using FIG. 1. Examples of the target film 2 include an insulating layer such as silicon oxide, a conductive layer containing a metal element or/and a stacked film thereof, but are not particularly limited. The resist layer 1 is applied to the entire upper surface of the predetermined etching target film 2 formed on the substrate 3, for example, by a spin coating method at a certain thickness. The resist layer 1 is, for example, ultraviolet curable (photocurable), and is a layer that is cured when irradiated with ultraviolet rays (light), but is in a liquid state when the layer is coated.

The template 10 is lowered with the uneven portion 10a facing downward from above the resist layer 1, and as shown in FIGS. 1 and 4A, the uneven portion 10a of the lower surface (pattern surface) 10u of the template 10 is pressed against the resist layer 1.

Specifically, first, the lower surface 10U of the third mesa portion 10C is pressed against the imprinting region e of the resist layer 1 to be imprinted. At the time of printing, the uneven portion 10a is pressed against the liquid resist layer 1 such that all of the uneven portions 10a are sunk in the resist layer 1 as shown in FIG. 1.

At this time, the resist layer 1 present on the outer side of the end edge 10C1 of the third mesa portion 10C is raised on the peripheral edge side of the third mesa portion 10C along the end edge 10C1 by the surface tension. As a result, a raised portion 1A of the resist layer reaching the second median surface EF of the second mesa portion 10B is formed on a peripheral edge side of a pattern surface 10U. In addition, the resist layer 1 present around the raised portion 1A is a liquid, and a part thereof is used to generate the raised portion 1A. Therefore, the liquid level of the resist layer 1 is temporarily lowered around the raised portion 1A, and the recess portion 1B is formed in the resist layer 1.

While pressing the template 10 against the resist layer 1, the resist layer 1 is irradiated with light (for example, ultraviolet rays) from above through the template 10 as indicated by the arrow in FIG. 1. The range irradiated with the ultraviolet rays is a range surrounded by a quadrangular frame-shaped light-shielding portion S and the inside of the light-shielding portion S. The photoresist is cured by irradiation with ultraviolet rays, and the shape of the uneven portion 10a of the third mesa portion 10C is transferred to the resist layer 1 as the pattern PA.

Since the template 10 blocks the ultraviolet rays with the light-shielding portion S having a quadrangular frame shape in a plan view, only the resist layer 1 located on the inside and below the light-shielding portion S can be cured. In the template 10, the lower region of the lower surface 10U of the third mesa portion 10C is a region corresponding to the shot region.

In the template 10, the second median surface EF of the second mesa portion 10B is provided inside the light-shielding portion S. Therefore, in addition to the shot region, the portion of the resist layer 1 of the raised portion 1A present in the periphery thereof can also be cured. Since the second median surface EF has a quadrangular frame shape in a plan view, the raised portion 1A is generated to surround the periphery of the pattern PA in a quadrangular frame shape in a plan view.

Since the resist layer 1 is cured by the second median surface EF to form the raised portion 1A, the raised portion 1A has a height that is the same as the height difference t3 shown in FIG. 2 at most. That is, the maximum height of the raised portion 1A can be controlled to about 200 nm to 500 nm.

As shown in FIG. 4B, the raised portion 1A is formed around the cured pattern PA, but the state in which the liquid resist layer 1 is not cured is maintained around the raised portion 1A due to the influence of the light-shielding portion s. That is, since the recess portion 1B and the resist layer 1 around the recess portion 1B are in a liquid state, when a certain period of time is elapsed, as shown in FIG. 4C, the liquid resist layer 1 flows from the periphery to fill the recess portion 1B, and the thickness of the resist layer 1 is recovered to the original thickness of the resist layer 1.

When the uncured resist in the periphery flows into the recess portion 1B and the raised portion 1A is not present, there is a concern that the liquid resist that flows in may flow into the region of the pattern PA and fill the peripheral portion of the pattern PA. Therefore, the height of the raised portion 1A needs to be higher than the unevenness of the pattern PA to some extent. It is possible to obtain the pattern PA in which defects such as pattern filling are not generated by providing the raised portion 1A having a necessary height.

As an example, the line height of a wiring portion formed by dual damascene technology in the insulating layer is about 60 to 75 nm, and the depth of the contact portion formed under the wiring portion is about several 10 of nm, for example, about 40 nm. In consideration of these sizes the height or thickness of the wiring portion exceeding 100 nm, the height of the raised portion 1A is set to about 200 nm to 500 nm. Therefore, even when the size of the uneven portion is slightly changed depending on the size of the object to be subjected to the imprint method, the raised portion 1A in which the pattern filling may be reliably prevented can be formed.

When the imprinting is completed, the template 10 is separated from the resist layer 1 of the region imprinted first on the substrate 3 by a predetermined driving device and a support, is moved onto another region adjacent to the substrate 3, and is imprinted on the corresponding region in the same manner as the above-described imprinting operation.

FIG. 4D shows a state where the template 10 is moved to the adjacent left region after the pattern PA is transferred by the previous imprinting, and the imprinting is performed on the uncured resist layer 1.

When the uncured resist layer 1 of the region adjacent to the template 10 is imprinted, the resist layer 1 present on the outside of the end edge 10C1 of the third mesa portion 10C is raised to the outside of the third mesa portion 10C along the end edge 10C1 by the surface tension. As a result, the raised portion 1A of the resist layer is present on the second mesa portion 10B up to the second median surface EF.

When the light (ultraviolet rays) is irradiated in the same manner as in the above-described case from this state, the pattern PA can be formed in the adjacent region, and the cured raised portion 1A can be formed. Therefore, it is possible to obtain the target pattern PA having no defects such as pattern filling even in the adjacent region.

A shot-to-shot gap G is generated between the raised portion 1A present at the end edge of the pattern PA formed by the previous transfer and the raised portion 1A present at the end edge of the pattern P formed by the imprint shown in FIG. 4D. The gap G can be used as a cutting width when the substrate 3 is divided by dicing or the like.

The above-described pressing operation is repeatedly performed on the resist layer 1 of the entire shot region of the substrate 3, for example, so that the pattern PA can be formed on the entire surface of the resist layer 1.

A pattern PA having no defects is formed on the resist layer 1, and the target film 2 is processed to correspond to the pattern PA by performing an etching process using the pattern PA of the resist layer 1. For example, a treatment of removing the bottom portion of the pattern PA formed in the resist layer 1 to expose the target film 2 is performed. Next, the target film 2 is etched using the resist layer 1 as a mask. When the target film 2 is etched, the raised portion 1A formed in the resist layer 1 as described later may remain.

As a result, a pattern corresponding to the pattern PA is formed on the target film 2. For example, as shown in FIG. 4E, the pattern PA is formed on the target film 2 on the substrate 3.

The remaining resist layer 1 is removed by, for example, an ashing process. After that, for example, when the target film 2 is an insulating layer, a metal such as copper (Cu) is embedded in a pattern formed on the target film 2, and becomes, for example, a part of a dual damascene wiring.

As shown in FIG. 4D, when the imprint method is performed on the resist layer 1 of the other adjacent region by the template 10, the raised portion 1A is formed in each of the imprinted regions. However, since the maximum height of the raised portion 1A is known in advance and the formation position is also known, there is little concern that a problem may occur in the processing of the next step. When the height of the raised portion is too large to exceed the height difference t3 shown in FIG. 2, there is a concern that a phenomenon such as the raised portion falling in the next step or the tip of the raised portion being broken may occur. In this case, there is a concern that a problem such as the occurrence of an etching failure portion in an etching process in the next step may occur.

### Comparative Example

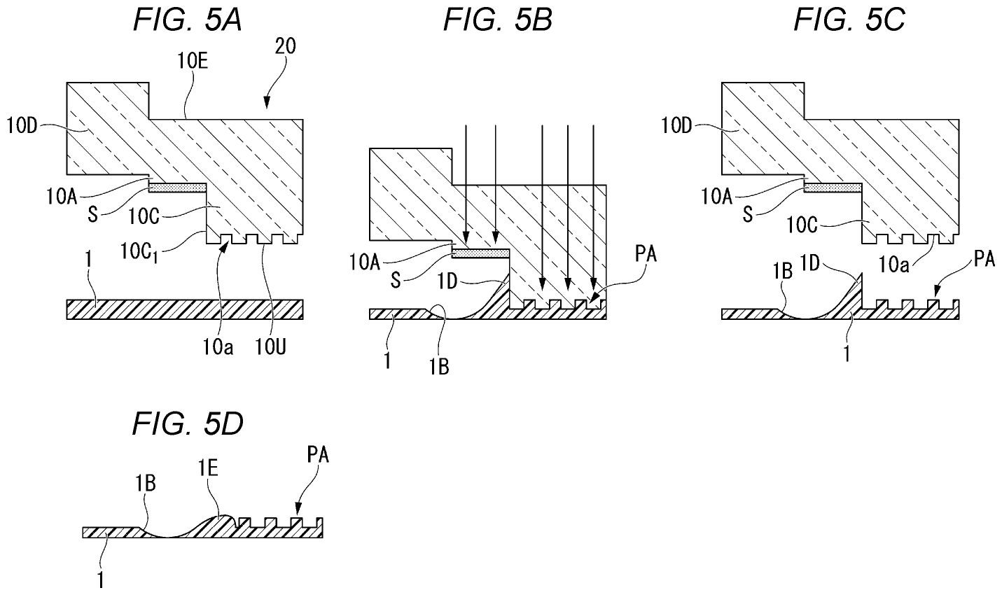

FIGS. 5A to 5D show a template 20 of a comparative example having no second mesa portion 10B and no second median surface EF. The template 20 of this example has the base material portion 10D, the first mesa portion 10A, and the third mesa portion 10C. The first mesa portion 10A in which the light-shielding portion S is formed and the pattern surface 100 having the uneven portion 10a is formed on the third mesa portion 10C are also the same as those of the template 10 described above. In the template 20, the first mesa portion 10A is formed on a peripheral side of the third mesa portion 10C in the plan view, and the light-shielding portion S is formed on the lower surface 10S (first median surface T) of the first mesa portion 10A.

When the imprint method is carried out on the resist layer 1 using the template 20, as shown in FIG. 5B, the raised portion 1D of the resist layer 1 is formed outside the end edge 10C1 of the third mesa portion 10C. Since the raised portion 1D is not irradiated with light (ultraviolet rays) during curing, the raised portion 1D remains as a liquid resist layer 1.

After that, when the template 20 is released from the resist layer 1 as shown in FIG. 5C in order to move the template 20 to another region, the liquid resist 1D is collapsed as shown in FIG. 5D and flows around the periphery as a liquid resist 1E. Therefore, the resist 1E flows to the pattern PA side in the periphery of the pattern PA after imprinting, and the liquid resist 1E fills a part of the pattern PA. Therefore, there is a problem in that a defective pattern PA having defects such as pattern filling is formed.

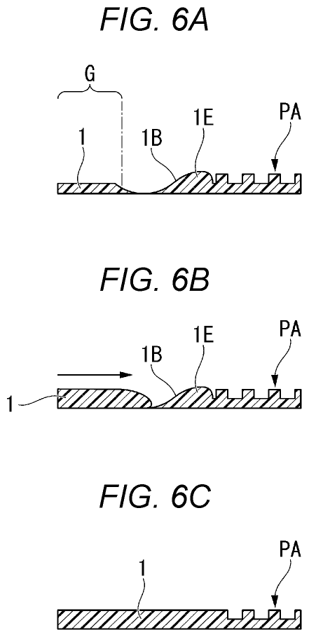

Although FIGS. 6A to 6C show the resist layer 1 after the pattern filling shown in FIGS. 5A to 5D is formed, the liquid resist 1E flows to the pattern PA side as shown in FIG. 6A. In addition, the recess portion 1B of the resist layer 1 is generated on the opposite side thereof. However, since the liquid resist flows from the resist layer 1 which remains as the liquid in the periphery, the recess portion 1B is filled with the liquid resist as shown in FIGS. 6B and 6C. However, as described above, the pattern filling is generated on the pattern PA side.

Meanwhile, as described above with reference to FIGS. 4A to 4E, it is found that when the resist of the raised portion 1A is irradiated with ultraviolet rays through the second median surface EF by the template 10 to be cured, the target pattern PA having no pattern filling can be formed.

### Method for Manufacturing Template

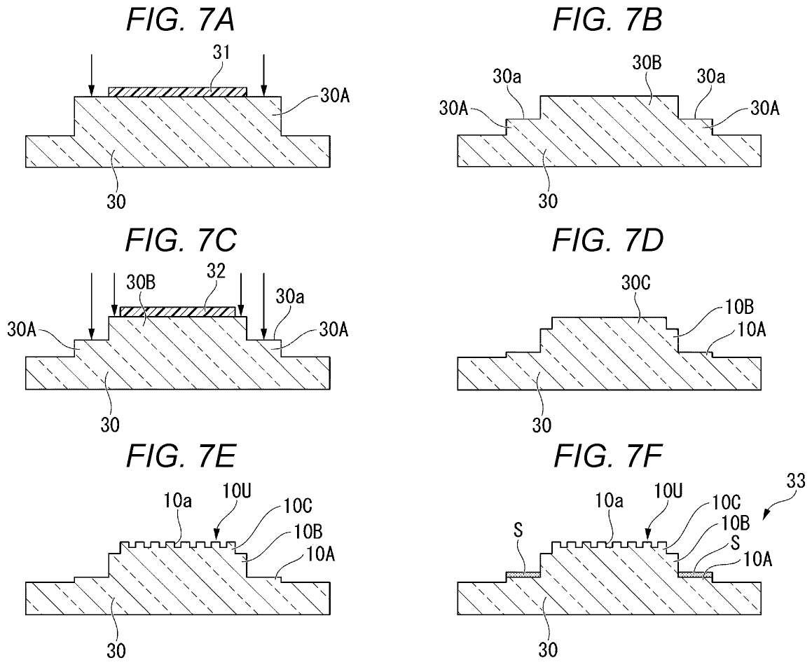

Next, a method for manufacturing the template 10 according to the first embodiment will be described with reference to FIGS. 7A to 7F.

First, a light-transmitting substrate 30 shown in FIG. 7A is prepared as a starting material, a resist pattern covering a region corresponding to the first mesa portion 10A described above is formed, and an elevated portion 30A corresponding to the formation region of the first mesa portion 10A, the second mesa portion 10B, and the third mesa portion 10C described above is formed by etching. FIG. 7A shows a state in which the elevated portion 30A is formed on the substrate 30. The substrate 30 is formed of, for example, a material capable of transmitting ultraviolet rays (ultraviolet rays), for example, quartz glass or a resin.

A first resist layer 31 that covers regions corresponding to the second mesa portion 10B and the third mesa portion 10C is formed on the upper surface of the elevated portion 30A shown in FIG. 7A, and reactive ion etching is performed to etch the peripheral side of the elevated portion 30A through the first resist layer 31. The etching forms a first protrusion portion 30B having a first stage portion 30a as shown in FIG. 7B.

Next, after the first resist layer 31 is removed, a second resist layer 32 that covers the region corresponding to the third mesa portion 10C described above is formed on the uppermost surface of the first protrusion portion 30B as shown in FIG. 7C. After the formation of the second resist layer 32, reactive ion etching (RIE) for etching the peripheral edge side of the first protrusion portion 30B through the second resist layer 32 is performed.

As shown in FIG. 7D, by this etching, a structure in which the first mesa portion 10A and the second mesa portion 10B are provided on the substrate 30 and a third protrusion portion 30C corresponding to the third mesa portion is provided on the second mesa portion 10B can be formed.

Thereafter, as shown in FIG. 7E, the third uneven portion 10a, which is a fine pattern, is formed on the upper surface of the third protrusion portion 30C to form the third mesa portion 10C. After that, when the light-shielding portion S is formed on the upper surface of the second mesa portion 10B as shown in FIG. 7F, a template 33 having the same structure as the template 10 shown in FIG. 1 can be obtained.

In the template 10 of the first embodiment described above with reference to FIGS. 1, 2, and 3A, a raised portion 1A made of a cured resist was formed at a position adjacent to the region where the pattern PA was formed, as shown in FIGS. 4A to 4E. The raised portion 1A can be formed by irradiating the second median surface EF provided in the second mesa portion 10B having no light-shielding portion S with ultraviolet rays through the second median surface EF.

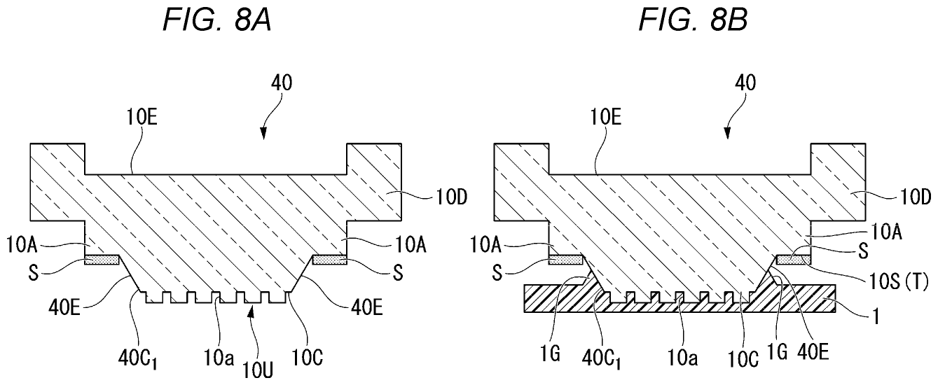

In order to form the raised portion 1A, a template of a first modification example shown below based on FIGS. 8A and 8B may be used, not limited to the template 10 of the first embodiment.

### Template of First Modification Example

The template 40 of the first modification example is made of a material capable of transmitting the same light (ultraviolet rays) as the template 10. The template 40 has the first mesa portion 10A and the third mesa portion 10C on the lower surface side of the base material portion 10D. A configuration in which the light-shielding portion S is provided on the lower surface 10S (first median surface T) of the first mesa portion 10A is the same as the template 10. A configuration in which the pattern surface 100 in which the uneven portion 10a is provided is formed on the lower surface of the third mesa portion 10C is the same as the template 10.

The template 40 is characterized by having a configuration in which the inclined surface 40E is formed in a portion from the inner periphery of the lower surface 10S (first median surface T) of the first mesa portion 10A to the outer periphery of the third mesa portion 10C.

The inclined surface 40E is inclined in a direction in which the width of the third mesa portion 10C gradually decreases from the inner periphery of the first mesa portion 10A to the outer periphery of the third mesa portion 10C in the cross section shown in FIGS. 8A and 8B.

In the template 40, the shape in a plan view formed by the first mesa portion 10A and the third mesa portion 10C is the same as the shape in the plan view shown in FIG. 3A. In FIG. 3A, the second median surface EF was a surface forming a step with the pattern surface 100 of the third mesa portion 10C. On the other hand, in the template 40, the configuration in which the inclined surface 40E is disposed at the position of the second mesa portion 10B shown in FIG. 3A is equivalent.

The height of the inclined surface 40E may be approximately the same as the height difference (level difference) t3 (refer to FIG. 2) described above, for example, approximately 200 nm to 500 nm.

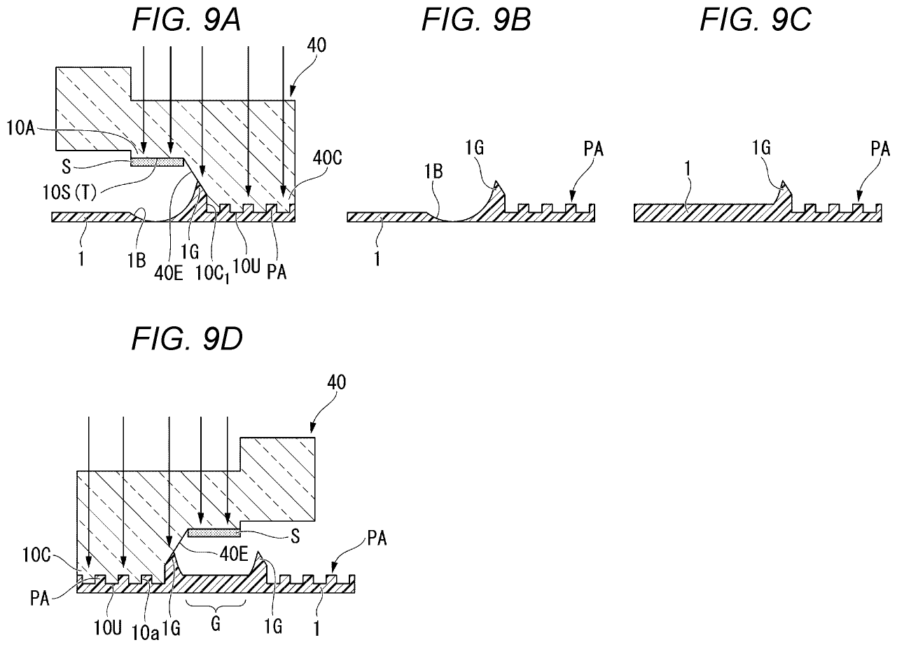

An imprint method of transferring the uneven portion 10a to the resist layer 1 using the template 40 having the inclined surface 40E will be described below with reference to FIGS. 9A to 9D.

The point of preparing the substrate 3 including the resist layer 1 and the target film 2 is the same as that in the embodiment described above.

The template 40 is lowered with the uneven portion 10a facing downward from above the resist layer 1, and as shown in FIG. 9A, the uneven portion 10a of the template 40 is pressed against the resist layer 1.

At this time, the resist layer 1 present on the outer side of the end edge 10C1 of the third mesa portion 10C is raised on the peripheral edge side of the third mesa portion 10C along the inclined surface 40E by the surface tension. As a result, the resist layer is formed with a resist layer having a raised portion 1G. In addition, the resist layer 1 present around the raised portion 1G is liquid, and a part thereof is used to generate the raised portion 1G. Therefore, the liquid level of the resist layer 1 is temporarily lowered around the raised portion 1G, and the recess portion 1B is formed in the resist layer 1.

While pressing the template 40 against the resist layer 1, the resist layer 1 is irradiated with light (ultraviolet rays) from above through the template 40 as indicated by the arrow in FIG. 9A. The range irradiated with the ultraviolet rays is a range surrounded by a quadrangular frame-shaped light-shielding portion S and the inside of the light-shielding portion S. The photoresist is cured by irradiation with ultraviolet rays, and the shape of the uneven portion 10a of the third mesa portion 10C is transferred to the resist layer 1 as the pattern PA required.

Since the template 40 blocks the ultraviolet rays with the light-shielding portion S having a quadrangular frame shape in a plan view, only the resist layer 1 located on the inside and below the light-shielding portion S can be cured. In the template 40, a lower region of the lower surface 40u of the third mesa portion 10C is a region originally required for the imprint.

In the template 40, the inclined surface 40E of the third mesa portion 10C is provided inside the light-shielding portion S. Therefore, in addition to the region originally required for the imprint, the portion of the raised portion 1G of the resist layer 1 present around the region can also be cured. Since the third mesa portion 10C has a quadrangular frame shape in a plan view as in the above-described embodiment, the raised portion 1G is generated to surround the periphery of the pattern PA in a quadrangular frame shape in a plan view.

The raised portion 1G is configured by curing the resist layer 1 of which the height is restricted by the inclined surface 40E, and thus has a height defined by the inclined surface 40E. That is, the maximum height of the raised portion 1G can be controlled to about 200 nm to 500 nm.

Also in the template 40, as in the template 10 described above, the target pattern PA having no pattern filling can be formed as shown in FIGS. 9B and 9C.

When the imprinting is completed in the previous region, the resist layer 1 in another adjacent region is imprinted with the template 40 as shown in FIG. 9D. A desirable pattern PA that does not cause pattern filling in other regions can be formed.

### Template of Second Modification Example

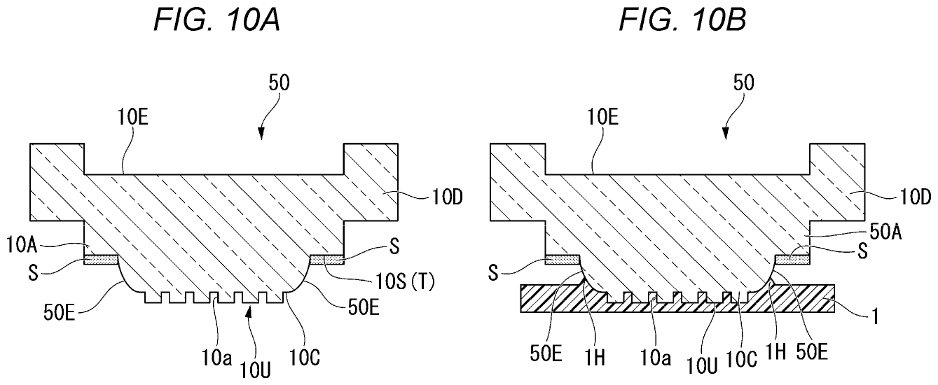

In order to form the pattern PA for the purpose of not having the pattern filling, the template is not limited to the template 10 of the first embodiment, and the template of the second modification example shown in FIGS. 10A and 10B may be used.

The template 50 of the second modification example is made of the same material as the template 10 and is capable of transmitting the same light (ultraviolet rays). The template 50 has substantially the same configuration as the previous template 40, but the convex curved surface 50E shown in FIGS. 10A and 10B is provided instead of the inclined surface 40E. The convex curved surface 50E is a curved surface that protrudes to the outside of the third mesa portion 10C.

FIG. 10A shows a cross section of the template 50, and FIG. 10B shows a state in which the template 50 is pressed against the resist layer 1.

The height of the convex curved surface 50E may be about the same as the previous height difference (level difference) t3 (refer to FIG. 2), for example, about 200 nm to 500 nm. The template 50 has the convex curved surface 50E of the third mesa portion 10C on the inside of the light-shielding portion S. Therefore, when the ultraviolet rays are irradiated from above the template 10, in addition to the region originally required for the imprint, a portion of the raised portion 1H of the resist layer 1 present in the periphery as shown in FIG. 10B can also be cured. Since the third mesa portion 10C has a quadrangular frame shape in a plan view, the raised portion 1H is generated to surround the periphery of the pattern PA in a quadrangular frame shape in a plan view.

Since the raised portion 1H is configured by curing the resist layer 1 of which the height is restricted by the convex curved surface 50E, the raised portion 1H has a height defined on the inclined surface. That is, the maximum height of the raised portion 1H can be controlled to about 200 nm to 500 nm.

Also in the template 50, the pattern PA for the purpose, which does not have the pattern filling, can be formed in the same manner as in the above-described template 40.

### Template of Third Modification Example

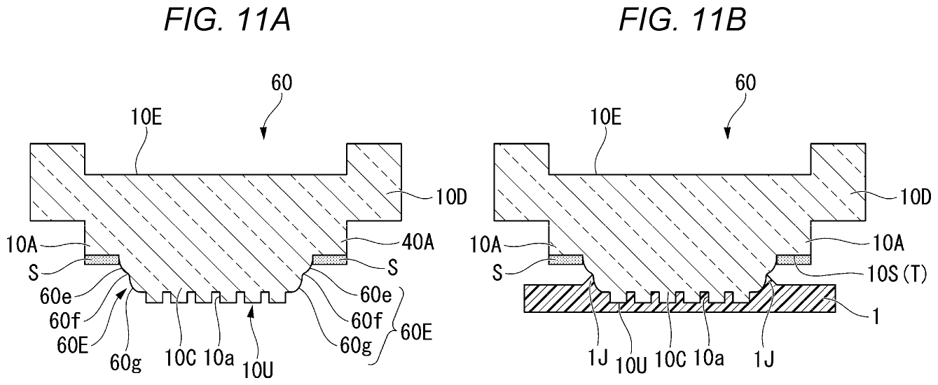

In order to form the target pattern PA having no pattern filling, the template is not limited to the template 10 of the first embodiment, and the template of a third modification example shown in FIGS. 11A and 11B may be used.

The template 60 of the third modification example is made of the same material as the template 10 and is capable of transmitting the same light (ultraviolet rays). The template 60 has substantially the same configuration as the previous template 40, but the uneven curved surface 60E is provided instead of the inclined surface 40E. The uneven curved surface 60E protrudes to the outside of the third mesa portion 10C. The uneven curved surface 60E has a shape in which the convex curved surface 60e that protrudes to the outside of the third mesa portion 10C, the concave curved surface 60f that protrudes to the inside of the third mesa portion 40C, and the convex curved surface 60g that protrudes to the outside of the third mesa portion 10C are combined.

The height of the uneven curved surface 60E may be approximately the same as the previous height difference (level difference) t3 (refer to FIG. 2), for example, approximately 200 nm to 500 nm.

FIG. 11A shows a cross section of the template 60, and FIG. 11B shows a state where the template 60 is pressed against the resist layer 1.

The template 60 has the uneven curved surface 60E of the third mesa portion 10C on the inside of the light-shielding portion S. Therefore, in addition to the region originally required for the imprint, the portion of the resist layer 1 of the raised portion 1J present around the region can also be cured. Since the third mesa portion 10C has a quadrangular frame shape in a plan view, the raised portion 1J is generated to surround the periphery of the pattern PA in a quadrangular frame shape in a plan view.

The raised portion 1J is configured by curing the resist layer 1 of which the height is restricted by the uneven curved surface 60E, and thus has a height defined on the inclined surface. That is, the maximum height of the raised portion 1J can be controlled to about 200 nm to 500 nm.

Also in the template 60, the pattern PA for a purpose which does not have a pattern filling can be formed in the same manner as in the above-described template 10.

### Template of Fourth Modification Example

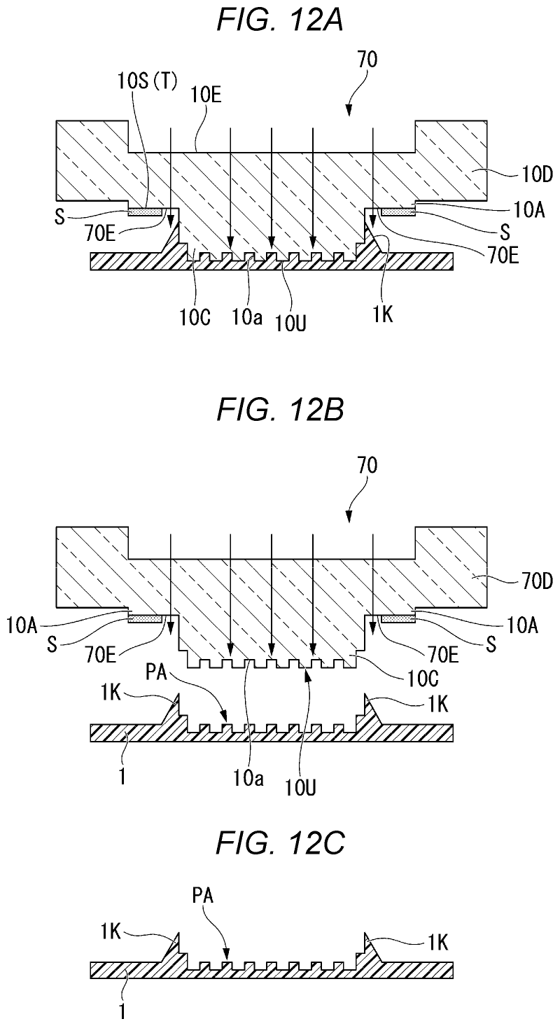

In order to form the target pattern PA having no pattern filling, a template of a fourth modification example shown in FIG. 12A may be used, not limited to the template 10 of the first embodiment.

The template 70 of the fourth modification example is made of a material capable of transmitting the same light (ultraviolet rays) as the template 10. The template 70 has the first mesa portion 10A and the third mesa portion 10C on the lower surface side of the base material portion 10D. A configuration in which the light-shielding portion S is provided on the lower surface 10S (first median surface T) of the first mesa portion 10A is the same as the template 10. A configuration in which the pattern surface 10U in which the uneven portion 10a is provided is formed on the lower surface 10S of the third mesa portion 10C is equivalent to the template 10.

The template 70 has a configuration in which the light-transmitting portion 70E is provided without providing the light-shielding portion S on the inner peripheral side of the lower surface 10S (first median surface T) of the first mesa portion 10A. The light-transmitting portion 70E is formed in a rectangular frame shape to surround the outside of the third mesa portion 10C in a plan view.

FIG. 12B shows a state in which the uneven portion 10a of the template 70 is pressed against the resist layer 1, and a raised portion 1K is formed on the periphery of the third mesa portion 10C.

In the template 70, in addition to the region originally required for the imprint, the portion of the raised portion 1K of the resist layer 1 present around the region can also be cured. Since the third mesa portion 70C has a quadrangular frame shape in a plan view, the raised portion 1K is generated to surround the periphery of the pattern PA in a quadrangular frame shape in a plan view.

In the template 70, the height difference between the lower surface 10S of the first mesa portion 10A and the pattern surface (lower surface) 10U of the third mesa portion 10C may be set to about 200 nm to 500 nm.

The raised portion 1K is configured by curing the resist layer 1 of which the height is restricted by the light-transmitting portion 70E, and thus has a height defined by the light-transmitting portion. That is, the maximum height of the raised portion 1K can be controlled to about 200 nm to 500 nm.

In the template 70, as shown in FIG. 12A, the ultraviolet rays transmitted through the light-transmitting portion 70E are irradiated to the resist layer 1, and the raised portion 1K can be cured. Therefore, the cured raised portion 1K shown in FIG. 12B or 12C can be provided, and the target pattern PA having no pattern filling can be formed in the same manner as in the case of imprinting using the template 10.

### Template for Fifth Modification Example

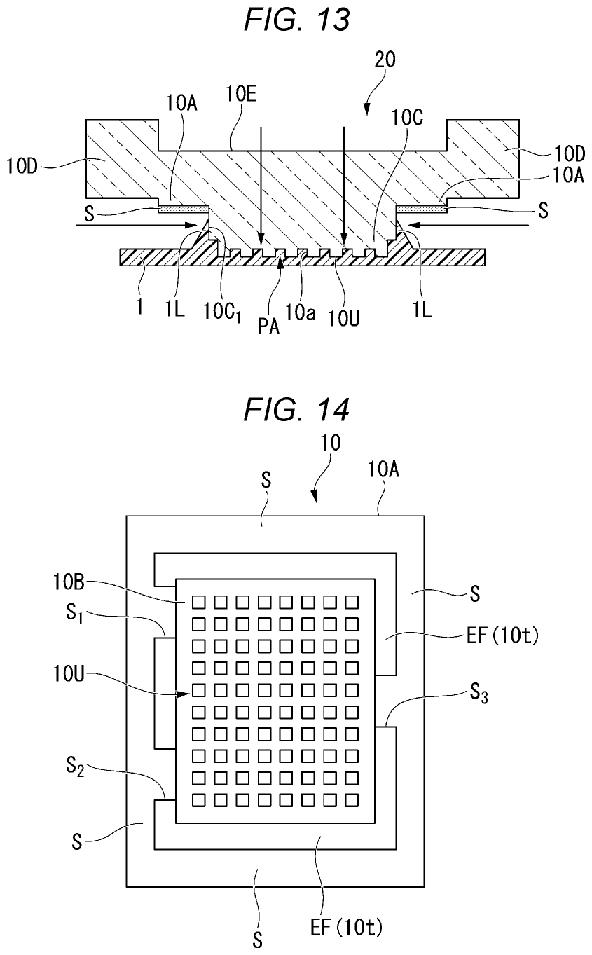

In order to form the target pattern PA having no pattern filling, the imprint method described below may be performed using the template of the fifth modification example shown in FIG. 13, not limited to the template 10 of the first embodiment.

The template of the fifth modification example has the same configuration as the template 20 shown as a comparative example.

As shown in FIG. 13, the uneven portion 10a of the template 20 is pressed against the resist layer 1, and light (ultraviolet rays) is irradiated from a peripheral side of the template 20 to the resist layer 1 in parallel to the surface direction (the lateral direction in FIG. 13) of the resist layer 1 along the gap space formed between the template 20 and the resist layer 1. Since the raised portion 1L of the resist layer 1 is generated on the outside of the end edge 10C1 of the third mesa portion 10C of the template 20 at the time of imprinting, the raised portion 1L can be cured by irradiation with ultraviolet rays from the lateral direction.

The desired pattern PA can be formed by irradiating the imprinting region of the resist layer 1 with ultraviolet rays from above the template 20 shown in FIG. 13, and the raised portion 1L can be cured.

In the present modification example, the template itself has the same configuration as the template 20 shown as a comparative example, but the imprint method (the light irradiation method) is different from that of the comparative example.

Since the raised portion 1L is cured, the target pattern PA in which the pattern is not embedded can be obtained as in the second to fourth modification examples.

FIG. 14 shows a modification example of the shape of the light-shielding portion S in a plan view.

As shown in FIG. 14, a structure can be adopted in which extending portions S1, S2, and S3 are provided in a portion of the light-shielding portion S, and the extending portions S1, S2, and S3 are provided in a portion in which the pattern surface 10U is adjacent to the first median surface T.

### Template for Sixth Modification Example

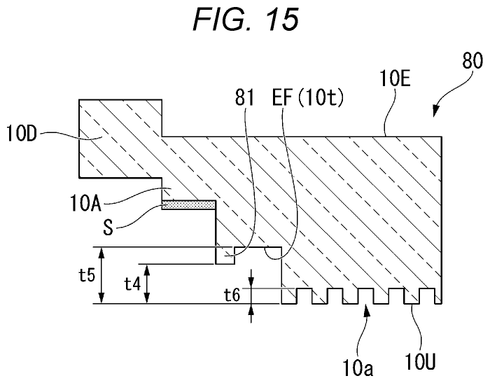

FIG. 15 shows a template 80 of a sixth modification example.

In the template 80, a wall portion 81 protruding downward from the second median surface 10t (EF) is provided on the second median surface 10t (EF). In this modification example, a configuration capable of preventing the liquid resist from crawling up from the second median surface 10t is adopted.

In the template 80, when a height from the lower end of the wall portion 81 to the pattern surface is t4, a height from the second median surface 10t to the pattern surface is t5, and a depth of the unevenness of the pattern is t6, it is preferable that the relationship of t5>t4>t6 is satisfied.

### Templates of Seventh to Ninth Modification Examples

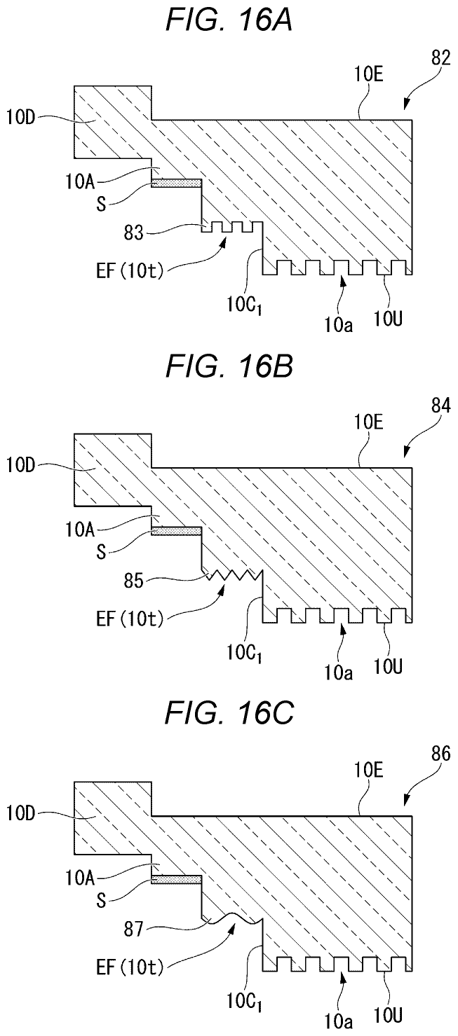

FIG. 16A shows a template 82 of a seventh modification example.

In the template 82, the second median surface 10t (EF) is a surface having a rectangular waveform-shaped uneven portion 83 in a cross-sectional view instead of a flat surface.

FIG. 16B shows a template 84 of an eighth modification example.

In the template 84, the second median surface 10t (EF) is formed of a surface having a triangular waveform-shaped uneven portion 85 in a cross-sectional view instead of a flat surface.

FIG. 16C shows a template 86 of a ninth modification example.

In the template 86, the second median surface 10t (EF) is a surface having a sinusoidal shape uneven portion 87 in a cross-sectional view instead of a flat surface.

The second median surface 10t (EF) is not limited to the flat surface as in the above examples, and may have various shapes. In this modification example, the liquid resist can reduce the speed of passing through the second median surface 10t.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An imprint method for forming a pattern by pressing a light-transmitting template against an imprinting region of a photocurable imprint material disposed on a substrate, the light-transmitting template including a pattern surface having an uneven portion, the method comprising:
preparing a template including a light transmission restricting film adjacent to the pattern surface;
preparing the substrate including the imprint material; and
performing imprinting by irradiating the imprint material with light in a state where the pattern surface is pressed against the imprint material,
wherein, when irradiating the imprint material with light, (i) the imprint material in the imprinting region and (ii) the imprint material raised at an end edge of the pattern surface adjacent to the imprinting region, are exposed, and
the imprint material in the imprinting region is cured, and a raised portion of the imprint material that is raised on the end edge is cured, while maintaining a height and a shape of the raised portion.

2. The imprint method according to claim 1,
wherein the template includes a light transmission restricting film positioned adjacent to the pattern surface and separated from the end edge of the pattern surface and a median surface, the median surface disposed between the end edge of the pattern surface and the light transmission restricting film with a height difference larger than a height difference of the uneven portion relative to the end edge of the pattern surface.

3. The imprint method according to claim 1,
wherein the template includes a light transmission restricting film positioned adjacent to the pattern surface and is separated from the end edge of the pattern surface and a median surface, the median surface disposed between the end edge of the pattern surface and the light transmission restricting film with an inclined surface having a height difference larger than a height difference of the uneven portion with respect to the end edge of the pattern surface.

4. The imprint method according to claim 3,
wherein the inclined surface has a convex curved surface, a concave curved surface, or a curved surface in which the convex curved surface and the concave curved surface are combined.

5. The imprint method according to claim 1,
wherein, in a state where the pattern surface of the template is imprinted against the imprint material, when irradiating the imprint material with light, the imprint material of the raised portion is irradiated with light from a side of the template.

6. A light-transmitting template used for imprint lithography for transferring a pattern to an imprint material, the template comprising:
a base material portion;
a first mesa portion protruding with respect to one surface of the base material portion and having a first median surface;
a second mesa portion protruding with respect to the first median surface of the first mesa portion and having a second median surface; and
a third mesa portion protruding with respect to the second median surface of the second mesa portion and the third mesa portion having a pattern surface including an uneven portion,
wherein a light transmission restricting film adjacent to the second mesa portion is disposed on the first median surface, and
a level difference between the second median surface of the second mesa portion and the pattern surface is larger than a height of the uneven portion.

7. The template according to claim 6,
wherein, when the pattern surface is pressed against the imprint material, the second median surface is a surface that comes into contact with a raised portion of the imprint material, which is raised along an end edge of the third mesa portion, to control a height of the raised portion.

8. The template according to claim 6,
wherein the second mesa portion is formed at a position in which the second mesa portion surrounds the third mesa portion in a plan view.

9. The template according to claim 6,
wherein the first mesa portion is formed at a position in which the first mesa portion surrounds the second mesa portion in a plan view.

10. The imprint method according to claim 1, wherein the light-transmitting template is transparent to ultra-violet light.

11. The imprint method according to claim 1, wherein the light transmission restricting film includes a metal.

12. The imprint method according to claim 2, wherein the light transmission restricting film includes a metal.

13. The template according to claim 6, wherein the light transmission restricting film includes a metal.

14. The template according to claim 6,
wherein the second median surface has a convex curved surface, a concave curved surface, or a curved surface in which the convex curved surface and the concave curved surface are combined.
